(19) United States
(12) Patent Application Publication
(10) Pub. No.: US 2024/0202396 A1
(43) Pub. Date: Jun. 20, 2024

(54) TEST ASSEMBLY AND METHOD FOR EMULATING THE PHASE CURRENTS OF AN ELECTRIC MOTOR FOR TESTING A POWER ELECTRONICS CONTROL UNIT

(71) Applicant: dSPACE GmbH, Paderborn (DE)

(72) Inventors: Philipp KEMPER, Paderborn (DE); Tobias SCHICKS, Paderborn (DE)

(73) Assignee: dSPACE GmbH, Paderborn (DE)

(21) Appl. No.: 18/540,443

(22) Filed: Dec. 14, 2023

(30) Foreign Application Priority Data
Dec. 14, 2022 (DE) 10 2022 133 311.6

(51) Int. Cl. G06F 30/20; G01R 19/165

(52) U.S. Cl. CPC G06F 30/20; G01R 19/16576

(57) ABSTRACT

A test assembly and a method for emulating the phase currents of an electric motor for testing a power electronics control unit, which is designed to control the electric motor and can be connected to the test assembly. The test assembly has an inductor emulator that simulates the electric motor as an electrical load for the control unit using a power electronics circuit, wherein the inductor emulator acts as a power source. Furthermore, the test assembly has a testing device that is designed to switch the inductor emulator to another operating state depending on an analysis of a variable dependent on an output voltage of the control unit.

This nonprovisional application claims priority under 35 U.S.C. § 119(a) to German Patent Application No. 10 2022 133 311.6, which was filed in Germany on Dec. 14, 2022, and which is herein incorporated by reference.

### BACKGROUND OF THE INVENTION

### Field of the Invention

The present application relates to a test assembly and to a method for emulating phase currents of an electric motor for testing a power electronics control unit.

### Description of the Background Art

Devices for executing open- and/or closed-loop tasks in vehicles are also referred to as control units. Control units in vehicles, in particular motor vehicles, can have a computing unit, memory, interfaces, and possibly other components, which are required for processing input signals with input data in the control unit and for generating control signals with output data. The interfaces are used to receive the input signals or to output the control signals.

In battery electric vehicles, there is a so-called motor control unit via which the drive motor is supplied with electrical energy from a battery, e.g., a traction battery. The motor control unit has an inverter that converts the direct voltage provided by the battery into alternating voltage, which is used to supply the motor.

To test the motor control unit, emulators are provided which simulate the behavior of the motor by providing the motor control unit with electrical currents which simulate the phase currents of the various windings of the motor.

If the inverter of the motor control unit is switched off or the semiconductor power switches are switched to be nonconductive for another reason, this state is called inverter blocking. A realistic emulation of the motor is desired for this state.

### SUMMARY OF THE INVENTION

It is therefore an object of the present invention to provide a test assembly for emulating the phase currents of an electric motor for testing a power electronics control unit that is designed to control the electric motor and can be connected to the test assembly.

In an example, the test assembly has an inductor emulator that simulates the electric motor as an electrical load for the control unit using a power electronics circuit, and has a testing device that is designed to switch the inductor emulator to another operating mode depending on an analysis of a variable dependent on an output voltage of the control unit.

Such a test assembly for emulating the phase currents can also be referred to as a simulator.

Furthermore, a method is proposed for emulating the phase currents of an electric motor using a test assembly for testing a power electronics control unit which is designed to control the electric motor and can be connected to the test assembly. The method has the following method steps: using an inductor emulator that simulates the electric motor as an electrical load for the control unit using a power electronics circuit, and using a testing device that is designed to switch the inductor emulator to another operating mode depending on an analysis of a variable dependent on the output voltage of the control unit.

The test assembly or the method for emulating the phase currents of an electric motor for testing a power electronics control unit have the advantage that certain operating modes of the control unit, such as, for example, the inverter blocking, can be reliably detected by analyzing a variable that depends on the output voltage at an output of the control unit. An advantageous handling of the so-called inverter blocking of the control unit can be achieved thereby. Consequently, secure use of this inverter blocking and its automatic detection are possible in particular. It is also possible, e.g., to avoid having to switch off the inductor emulator manually when the inverter blocking is detected. An automatic processing of this operating state of the inverter blocking is possible. As a result of the analysis, the inductor emulator can be switched to another operating mode, for example, the inductor emulator can be switched off. Alternatively, the inductor emulator can be switched so that it acts as a voltage source.

The test assembly can have at least one inductor emulator, which simulates the electric motor as an electrical load for the control unit by means of a power electronics circuit. In particular, the test assembly can have at least one inductor emulator per phase. The test assembly can be a device that is intended to test control units, in particular power electronics control units, for their function. To achieve this, an electric motor is emulated through its phase currents for the control unit by the test assembly, so that it is possible to test the control unit in various situations without having to connect an actual electric motor to the control unit. This is more cost-effective and more efficient than actually having to connect an electric motor. However, the control unit can also be connected to a battery or to an emulation of a battery, so that the control unit can be tested for all possible situations by the connected devices. All functions that are on the control unit, for example, stored in an electronic memory, can also be thus tested in a simple manner.

Emulation of the phase currents can mean that phase currents that are suitable for control by the control unit are provided by the test assembly to the control unit. The testing device is controlled in particular by the output voltage of the control unit. The output voltage of the control unit therefore supplies the control values which are applied to the at least one inductor emulator of the testing device, so that the desired phase current is set as an electrical output variable. The phase current here results from the output voltage of the control unit, e.g., by calculating corresponding mathematical motor models of the at least one inductor emulator of the testing device. For this purpose, the real electrical variables at the input are detected by measurement and processed further within the framework of the mathematical models, taking into account the desired output variables in the model; corresponding control sequences, therefore, sequences of control values, are calculated for the power switches, present in the power electronics circuit, and applied to the power electronics circuit.

Inverter blocking can mean that the power switches forming the end stage of the inverter in the control unit are switched to blocking. It should be noted that when the end stage is switched off in this way, the current supplied by the inductor emulator to the control unit only reduces to zero after a certain time, because with an electric motor, its inductors store energy which dissipates as a fault current. This fault current flows away via one of the freewheeling diodes, which are connected in parallel to the power switch in the end stage. This fault current can be simulated using the inductor emulator. Moreover, it can be that the inductor emulator is provided with a higher voltage than the control unit, which is supplied with the battery voltage. Therefore, the inductor emulator can then regulate the fault current via the freewheeling diode according to a model value. However, once the current has dissipated, the inductor emulator must set a current of exactly zero in order to realistically reproduce the behavior of the simulated inductors. However, a small deviation from ideal zero results in either the upper or lower freewheeling diode becoming conductive, as there is no other path for this fault current. At the same time, however, when a freewheeling diode becomes conductive, the voltage jumps either above the upper or lower potential of the D link voltage. Feedback with the mathematical model of the inductor emulator of the test assembly can then lead to the emulated current oscillating up and down and thus also to a corresponding oscillation behavior of the output voltage of the control unit. Correct emulation of the current is therefore not possible. The proposal according to this application provides a remedy for this.

According to the application, the operating state of the inverter blocking is detected based on a variable that depends on the potential curve at the output of the control unit, therefore, on the output voltage of the control unit. If the inverter blocking is detected, the current control of the inductor emulator is switched to another operating mode.

The test assembly has the task of emulating phase currents of an electric motor. This means that the test assembly outputs the currents that an electric motor would output in the respective operating state. The test assembly can also be called an emulator. This makes it possible to test a power electronics control unit that is designed to control the electric motor and is therefore connected to the test assembly. In particular, for control units that are intended for driving an electric vehicle, such power electronics control units are provided that have a converter with which the electric motor can be controlled. A converter or inverter has power electronics such as semiconductor power switches, which are designed, for example, as power transistors.

An electric motor is used that is controlled with alternating current. In this regard, such an electric motor has, for example, three or six phases. More or fewer phases are also possible. Depending on the motor type, the number of phases can vary, e.g., five, seven, etc., are also possible. The test assembly is designed to simulate at least one phase, but also multiple phases or all phases.

The power electronics control unit is a control unit that can convert the direct voltage from the battery into an alternating voltage. For this purpose, the control unit has at least one converter, which can also be called an inverter, which is usually controlled using pulse width modulation. The control unit has additional functions such as self-tests or test functions for the electric motor or the connected devices, which, for example, can be accessed via a communication interface, for example, via a CAN bus. Therefore, in addition to the inverter, the control unit also has a communication interface and, for example, a microcontroller which carries out the function of the control unit.

The test assembly has at least one inductor emulator per motor phase, which emulates the electric motor as an electrical load for the control unit using a power electronics circuit. The test assembly has, e.g., a power electronics circuit which has parallel half-bridges. The half-bridges can have multiple stages. The power electronics circuit can act here as a fast-reacting current source.

An inverter can also be used to emulate the phase currents, which inverter converts the supply voltage applied to the inductor emulator into alternating voltage. This inverter is then the power electronics circuit as claimed and acts as an inductor emulator.

Depending on an analysis of the variable dependent on the output voltage of the control unit, the testing device switches the inductor emulator to another operating mode when predefined conditions are present. This could be, for example, a switching off.

However, the testing device continues to analyze the output voltage of the control unit or the variable dependent thereon after the inductor emulator is switched to the other operating mode. The testing device monitors the variable, dependent on the output voltage, in order to switch the inductor emulator back to another, e.g., the previous, operating mode when the variable, dependent on the output voltage, changes accordingly; i.e., the so-called inverter blocking is no longer present.

Therefore, operating mode can be understood to mean: the normal functioning of the inductor emulator, which the inductor emulator provides the phase currents depending on the output voltage of the control unit, as well as an operating mode in which the inductor emulator is in the other operating mode. In the other operating mode, e.g., no phase current can be generated; i.e., the inductor emulator is switched off. It is also possible for the inductor emulator to act as a voltage source in the other operating mode, i.e., provides the control unit with a voltage by which the phase currents are then generated. An inductor emulator that can act as a voltage source may require a different hardware design than the inductor emulator that can act as a current source. It is possible to design the inductor emulator in terms of hardware so that it can act as both a voltage source and a current source and that it is possible to switch between the two operating modes. This is advantageous, e.g., when detecting the inverter blocking.

The same applies to the method for emulating the phase currents of an electric motor.

The testing device not only has a software and/or hardware logic to detect the so-called inverter blocking but also a further logic that uses, for example, the output voltage of the control unit to detect which current the electric motor would then output for this specific output voltage. For this purpose, the testing device has, for example, a model, in particular a motor model, which establishes these relationships between the output voltage of the control unit and the current that the inductor emulator outputs to the control unit. This model is stored, for example, in an electronic memory.

The testing device can be controlled, for example, by the output voltage of the control unit. The output voltage of the control unit therefore supplies the control values which are applied to the testing device so that the desired phase current is set as an electrical output variable.

In order to efficiently test the functionality of electronic control units, such test assemblies or simulations are used to test the control unit in a wide variety of situations to ensure that it functions as intended. The system comprising a testing device, control unit, and, optionally, a battery connected to the control unit can therefore be referred to as a hardware-in-the-loop setup (HiL setup). The control unit is not only addressed at the signal level by the testing device, but the power connections are also stimulated. The setup can therefore also be referred to as a power hardware-in-the-loop emulator (power HiL). The hardware to be tested, thus, e.g., the motor control unit with possibly a battery, can be referred to as the “device under test.”

If the control unit is in an operating mode in which electrical energy is supplied as alternating voltage to the connected electric motor, the power switches of each half-bridge can be switched on, e.g., in a cyclically alternating manner. This is called pulse width modulation operation or PWM operation for short. When the control unit is in the PWM mode, there is precisely one potential change in the output voltage of the control unit in a defined time interval. In this respect, the characteristic time interval depends on the PWM frequency of the control unit. Via the pulse width modulation of the power switches, the direct voltage of the battery is used to modulate the control unit output voltage, which impresses the desired sinusoidal currents into the motor winding.

The state of the control unit can be determined by measuring the output voltage of the control unit and evaluating the number of potential changes in a defined time interval.

The following characteristic cases can be differentiated.
1. Static operation: no potential change in the observed interval
2. Dynamic operation (PWM): two potential changes in the observed interval
3. Inactive operation (inverter blocking): more than two potential changes in the observed interval

Based on this realization, it emerges that, for example, based on more than two potential changes in an observed interval, the inverter blocking causes the operating mode of the inductor emulator to change. In particular, the testing device can cause the inductor emulator to be switched off. Alternatively, the testing device can switch the inductor emulator to an operating mode in which it acts as a voltage source. In the operating mode as a voltage source, the inverter blocking does not cause the current to oscillate up and down because a voltage is impressed here.

In an example, the inductor emulator acts as a power source. For this purpose, the test assembly has, e.g., a power electronics circuit which has parallel half-bridges. Multiple half-bridges can be connected in parallel and together generate the phase current for one phase of the electric motor. The respective half-bridges can have multiple stages with power semiconductor switches. The amount of current delivered can be influenced via the stages.

The inductor emulator is thus operated as a current source, which is regulated by the testing device depending on an analysis of an output voltage of the control unit, e.g., by switching it to another operating mode. In particular, the inductor emulator can be switched off in the other operating mode or act as a voltage source. The level of current that the inductor emulator emits can also be adjusted, for example, depending on the output voltage of the control unit, e.g., via the power semiconductor switches of the half-bridges.

An inverter can also be used for emulating the phase currents, which inverter converts the supply voltage applied to the inductor emulator into alternating voltage. This inverter is then the power electronics circuit as claimed.

In an example, the test assembly can be designed to feed a current into the output of the control unit that depends on the output voltage of the control unit and was generated by the inductor emulator. As already shown above, by feeding the current into the control unit by the inductor emulator, the behavior of an electric motor during operation can be reliably simulated depending on the output voltage of the control unit.

It is proposed that the other mode of operation is to turn off the inductor emulator. It is then deactivated, i.e., switched off, and the output of the inductor emulator becomes high-impedance. Therefore, after the current flowing in any output inductor has been reduced, a current of 0 A is established and the condition is met that when a so-called inverter blocking of the control unit is detected, no more current is supplied to the control unit by the inductor emulator. Alternatively, a switch can be made to an operating mode in which the inductor emulator acts as a voltage source.

In an example, the testing device can be designed to carry out the analysis such that at least one change in the output voltage or the variable dependent thereon is evaluated in a predefined first time interval and the change in the operating mode of the inductor emulator takes place as a function of this evaluation. The analysis therefore describes the conclusions which the testing device draws, for example, from the time course of the output voltage of the control unit or the variable dependent thereon.

A change in this output voltage is evaluated in the first time interval. These are, for example, changes in potential or the exceeding of thresholds. If the criterion is met that there is an inverter blocking of the control unit, then the inductor emulator is switched off as a function of this evaluation.

Furthermore, it is proposed that the testing device has a threshold value comparator which is designed to compare the output voltage or the variable dependent thereon, e.g., the output voltage or a measurement voltage dependent thereon, with at least one threshold value, wherein the testing device is designed to carry out the evaluations depending on this comparison. The analysis is therefore carried out with one threshold value, wherein there can also be multiple threshold values. This threshold value comparison, i.e., whether this threshold is exceeded or not, then determines whether the testing device arrives at such an evaluation that the inductor emulator is switched off.

Moreover, it is proposed that the threshold value comparator can be designed to detect a rising and/or a falling edge of the output voltage or the measurement voltage. Potential changes can be detected particularly well thereby.

For example, the threshold value comparator can be designed to compare the output voltage or the measurement voltage with at least two threshold values, wherein the threshold value comparator is further designed to only detect a rising or falling edge based on the comparisons in which at least two threshold values are exceeded within a predefined second time interval. A rising or falling edge is reliably detected thereby.

Furthermore, the testing device can have a counter which can be designed to count rising edges or falling edges of the output voltage or the measurement voltage in a predefined third time interval which is as long as or shorter than the first predefined time interval, wherein the testing device is designed to carry out the evaluations depending on a counter reading of the counter. This makes it possible, for example, to detect whether more than a predefined number of potential changes have occurred in one cycle. If this is the case, it can be concluded that an inverter blocking has occurred. In the case of the inverter blocking, these potential changes are caused by the freewheeling diodes becoming conductive. One consequence of this is that the simulated current oscillates up and down. It is also possible for the counter to be designed in terms of hardware and/or software.

Moreover, it is provided that the output voltage or the variable dependent thereon continues to be analyzed by the testing device even after the inductor emulator has been switched off. Depending on this further analysis, the inductor emulator is also switched on again. This then detects when the inverter blocking ends, so that the inductor emulator is then necessary again to show the inductors and thus the phase currents of the simulated electric motor.

The inductor emulator can be connected to the control unit via an inductor network. The inductor network, which can be formed of coupled inductors, can have two basic functions. It is initially intended to prevent crosscurrents between the parallel bridges of the circuit. It also serves as an inductive voltage divider to combine multiple discrete voltages, which are provided, e.g., by the circuit's parallel bridges.

Moreover, it is proposed that the power electronics circuit can have at least one bridge circuit with semiconductor switches as the power switches, in particular three bridge circuits, connected in parallel, with semiconductor switches. If each half-bridge has multiple stages, also called levels, then the current delivered by the inductor emulator can be finely scaled in its size. Scaling is possible, depending on which semiconductor switches are closed or controlled accordingly in order to influence the current output. This makes it possible, in addition to the intrinsic DC link potential, to also apply the DC link center point to the inductor network in order to regulate the desired output current more dynamically and precisely. The semiconductor switches can be made, e.g., from silicon carbide, but also from other semiconductor materials suitable for power electronics. For example, silicon, germanium, or gallium nitride, or the like.

Furthermore, it is proposed to provide the test assembly with a respective inductor emulator and a respective testing device for each phase of the electric motor.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows an overall assembly with the control unit, the test assembly, and a battery;

FIG. 2 is a block diagram of the control unit and the test assembly;

FIG. 3 is a circuit diagram of the control unit with the connected test assembly and the battery;

FIG. 4 is a circuit diagram of an exemplary bridge of the inductor emulator;

FIG. 5 is an example of the inductor network;

FIG. 6 is a flowchart of the method;

FIG. 7 is a block diagram of the analysis of the output voltage or the variable dependent thereon;

FIG. 8 is a first voltage-time diagram; and

FIG. 9 is a second voltage-time diagram.

### DETAILED DESCRIPTION

FIG. 1 shows a block diagram of the overall assembly on which the present application is based. Test assembly S is connected to control unit SG in such a way that electrical signals are transmitted from control unit SG to test assembly S and vice versa. These electrical signals are currents or voltages. Connected to control unit SG is a battery B, which supplies control unit SG with electrical energy, as is then also the case in the vehicle. In this regard, battery B can be connected, for example, via a high-voltage network or directly to control unit SG. Battery B can also be designed as an emulation of a battery B, so that the behavior of control unit SG can be tested with emulations on both sides.

It is possible for an emulation of the battery to be carried out with the emulation of the phase currents on identical hardware. The power electronics circuit used to emulate the phase currents can also emulate battery B, e.g., in combination with a capacitor. A complete emulation environment of the control unit's power and signal connections can be created thereby. The advantage here is that the transferred electrical energy can remain in the system.

Control unit SG converts the direct voltage of battery B into an alternating voltage UDOUT using its converter, which has at least two power switches that are controlled with a pulse width modulation. Test assembly S is supplied with this alternating voltage UDOUT. It is then tested how control unit SG would control the electric motor simulated by test assembly S. Control unit SG can be supplied with various control signals in order to simulate different driving situations. Control unit SG then shows thereby how it would control the electric motor.

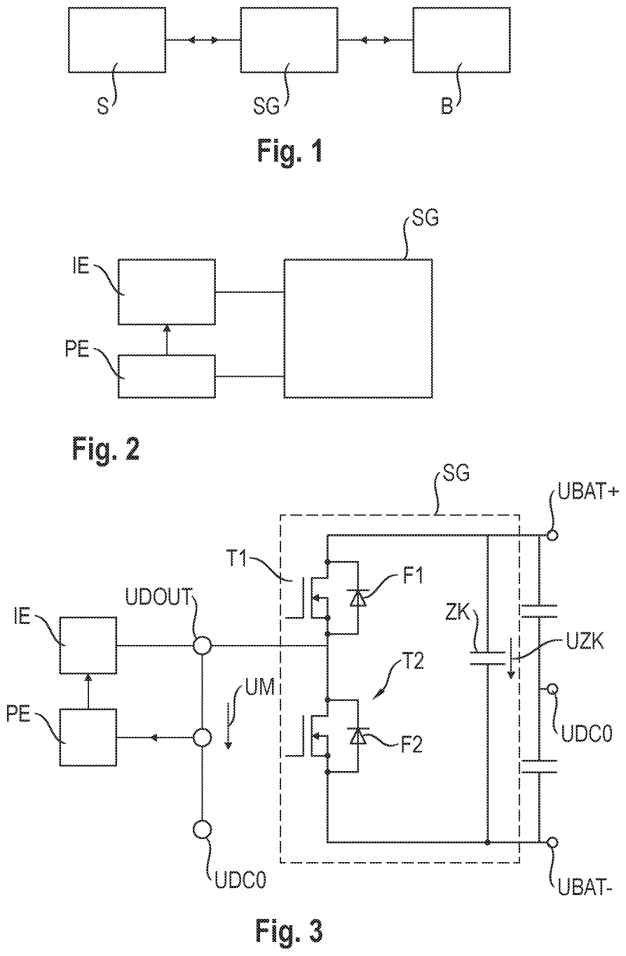

FIG. 2 now shows that test assembly S has two components: namely, inductor emulator IE and testing device PE. Testing device PE analyzes the output voltage UDOUT of control unit SG or the variable dependent on it, such as, e.g., measurement voltage UM. Depending on this analysis, testing device PE switches inductor emulator IE to another operating mode, that is, in particular when the above-mentioned inverter blocking was detected.

If the other state is the switched off state of the inductor emulator, then, as described above, the switched off inductor emulator IE no longer supplies any current after the electrical energy still in it has been reduced.

FIG. 3 shows the circuit of control unit SG with the circuitry using test assembly S with inductor emulator IE, testing device PE, and the connected battery B, which can also be emulated. If battery B is emulated by the same hardware which also comprises induction emulator IE, the two respective capacitors between UBAT+ and UDC0 and between UBAT− and UDC0 can be used to emulate the battery voltage UBAT+ against UBAT−. The power semiconductor switches can, e.g., be controlled so that they emulate battery B at the same time.

The output voltage UDOUT of control unit SG is detected via the measurement voltage UM by testing device PE. The voltage UM can be measured, e.g., against the reference voltage UDC0. It is also possible to measure against one of the battery potentials and to adjust the thresholds ThH and ThL accordingly. This is an advantage, e.g., in a setup with a real battery.

Control unit SG has two power switches T1 and T2, which are designed as transistors. These are accordingly semiconductor power switches.

Two freewheeling diodes F1 and F2 are then connected in parallel to the two transistors T1, T2. This bridge comprising transistors T1 and T2 and freewheeling diodes F1 and F2 is connected in parallel to a DC link capacitor ZK. This bridge is also parallel to battery B, which supplies the voltages UBAT+ or UBAT− to the control unit. The battery voltage UBAT+/− is also related to the reference potential UDC0. The DC link voltage UZK is absorbed via the DC link capacitor ZK. The alternating voltage is thus generated by the power switches T1 and T2, which are controlled by controllers in the pulse width modulation method.

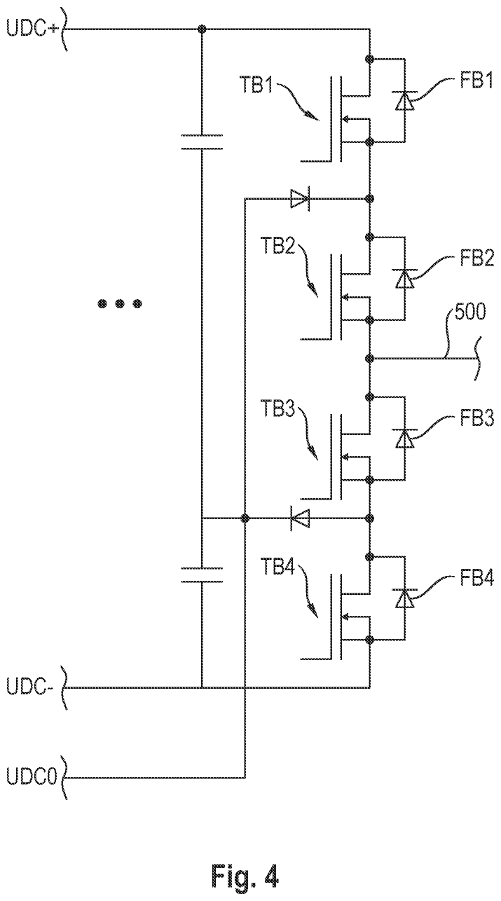

FIG. 4 shows by way of example a structure of a bridge in inductor emulator IE. The structure shown can correspond, e.g., to that of a 3L-NPC bridge. A preferred embodiment uses exactly three such bridges, with which the current emitted by inductor emulator IE via line 500 is then combined. For this purpose, the individual transistors TB1 to TB4 can be controlled accordingly, namely, by testing device PE.

The bridge shown has four power switches TB1 to TB4, each of which has a freewheeling diode, FB1 to FB4, connected in parallel. The reference potential UDC0 is connected between power switches TB1 and TB2 or power switches TB3 and TB4. By switching TB1 and TB2 to conduction, the UDC+ potential can be made available at tap 500. By switching TB3 and TB4 to conduction, the UDC− potential can be made available at tap 500.

A DC link of the circuit has two capacitors between the voltages UDC+ and UDC−. The DC link is divided and has a connection to the reference potential UDC0 in the middle between the two capacitors. Two diodes are provided between the reference potential UDC0 and the connections between the respective power switches. The mean potential of the DC link UDC0 can be made available at tap 500 via the diodes by turning on TB2 and TB3 and blocking TB1 and TB4.

Further bridges connected in parallel, not shown in FIG. 4, can be constructed accordingly. If they are designed like the bridge shown, they can also make these three potentials available at their respective taps 501, 502.

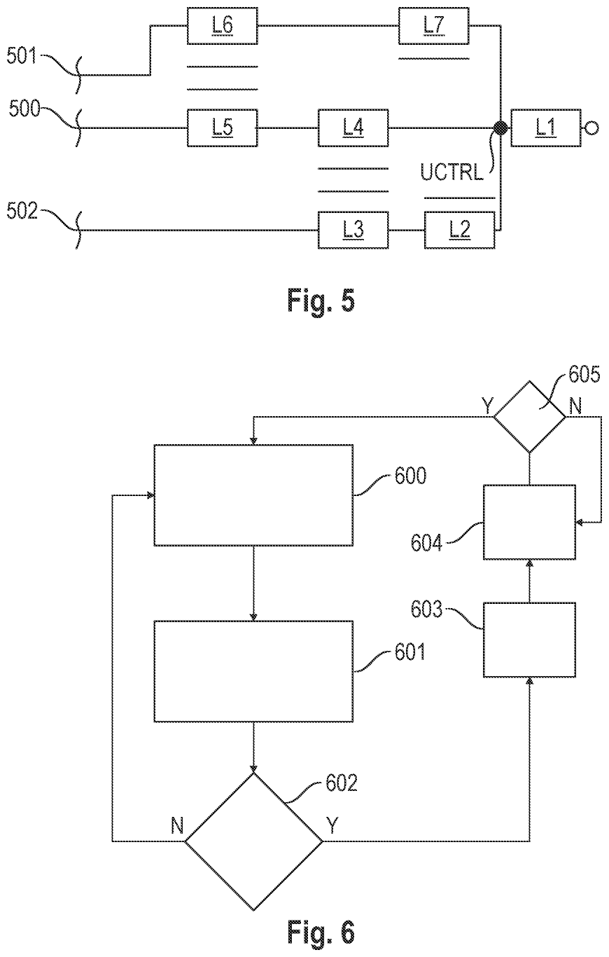

Shown in FIG. 5, connected to coupling inductor L1, are three branches of an inductor network with inductors L2 to L7. These inductors L2 to L7 have magnetic couplings. Iron cores, which are assigned to inductors L2 to L7, are also shown by the lines. The respective inductors L5/L6, L3/L4, and L2/L7 are magnetically coupled via the iron cores. The connection to control unit SG is made via coupling inductor L1.

Each branch of this inductor network is provided by way of example for a bridge of inductor emulator IE, as such a bridge is shown by way of example in FIG. 4. The bridge shown in FIG. 4 is connected to the inductor network via tap 500. Further bridges are connected to the inductor network via taps 501 and 502, so that the three partial currents of the three branches are then brought together via coupling inductor L1.

The bridge shown in FIG. 4 supplies the middle branch 500 of the inductor network of FIG. 5 with inductors L4 and L5 with a current that is combined with the other two branches. The other two branches 501 and 502 are supplied with a respective current from the other two bridges. Therefore, the total current of the three branches flows through coupling inductor L1 to output A.

The inductor network formed of the coupled inductors L5/L6, L3/L4, and L2/L7 has two basic functions. It is initially intended to prevent crosscurrents between the parallel bridges. It also serves as an inductive voltage divider to combine the 3 discrete voltages of a respective bridge, in the example shown a 3L-NPC bridge. With the help of this voltage divider, e.g., a 7 level topology is thus created by combining, e.g., three bridges. Before series inductor L1, e.g., seven discrete voltage levels can be switched as the control voltage UCTRL by combining different voltage levels from the various bridges.

If the inductor emulator is to act as a voltage source, a capacitor could be connected, e.g., instead of or in addition to coupling inductor L1.

FIG. 6 shows the method of the invention in a flowchart. In method step 600, inductor emulator IE is used to determine, based on the output voltage UDOUT of control unit SG or the measurement voltage UM, which current inductor emulator IE should output via its bridge circuit. In method step 601, testing device PE is used for this purpose and, in method step 602, it determines whether the output voltage UDOUT or the measurement voltage UM shows based on the analysis that inductor emulator IE should be switched to the other state in method step 603. If the analysis does not show this, the process returns from method step 602 to method step 600. If inductor emulator IE has been switched to the other state in method step 603, testing device PE then further analyzes in method steps 604 whether the output voltage UDOUT or the measurement voltage UM indicates that normal operation begins again after the inverter blocking. If this is detected in method steps 605, the process also returns to method steps 600. If this is not detected—the state of the inverter blocking is therefore still decisive —, the process returns to method step 604 and analyzes further.

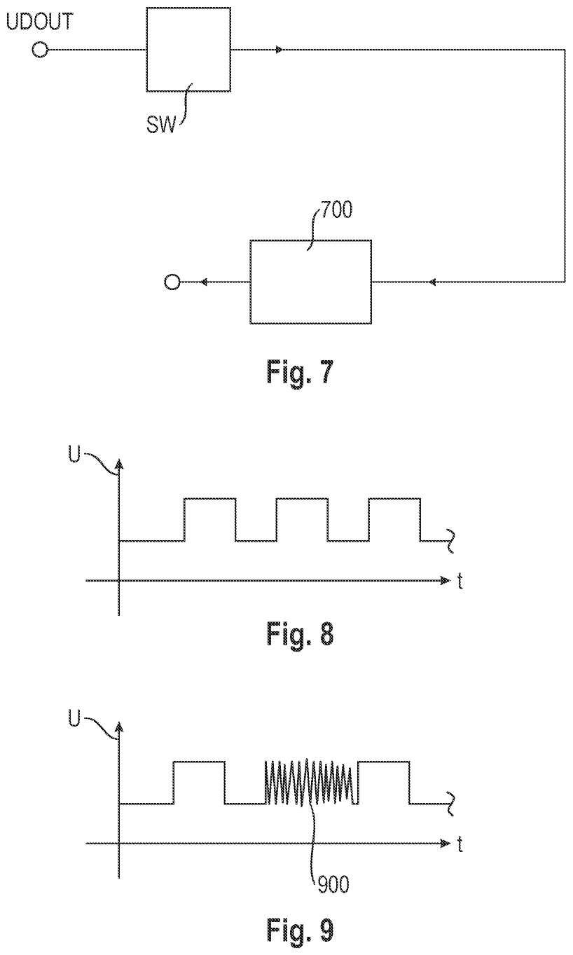

FIG. 7 shows in a block diagram the processing or analysis of the output voltage UDOUT or the measurement voltage UM dependent on it. This voltage UDOUT is supplied to threshold comparator SW. In threshold value comparator SW, the voltage UM can be compared with one or more threshold values. However, the exceeding of the threshold value is then also assessed based on whether it occurs within a certain time. This is also done with counters and comparing the counter reading with predetermined thresholds. In method step 700 it is then decided whether this analysis leads to switching inductor emulator IE to the other operating mode.

Threshold value comparator SW is in particular set up to analyze the measurement voltage UM within a first time interval. The first time interval can depend, e.g., on a periodic time of the emulated alternating current.

It can be detected that a rising edge is present in threshold value comparator SW, e.g., when the measurement voltage UM exceeds a first lower threshold value and then a second higher threshold value within a second time interval. In the same way, it can be detected that a falling edge is present, when the measurement voltage UM exceeds a first higher threshold value and then a second lower threshold value within the second time interval. If, e.g., more than a certain number of rising/falling edges now occur within the first time interval, an inverter blocking can be inferred and inductor emulator IE can be set to the other operating state.

Alternatively or additionally, it is also possible to count the number of rising and/or falling edges during a third time interval, which is as long as or shorter than the first time interval. If, as shown by way of example in FIG. 9, many rising and associated falling edges occur, then when a predefinable counter reading is exceeded, the state of the inverter blocking can be inferred and the inductor emulator can be set to the other operating state.

FIG. 8 shows the measured output voltage in the normal pulse width modulation operation in a first voltage-time diagram. A periodic square-wave voltage can be seen.

FIG. 9 shows in section 900 the measured output potential UM with many potential changes. Therefore, the number of potential changes can be used to decide whether an inverter blocking is present. As shown above, this oscillating behavior occurs when the current set by inductor emulator IE deviates from ideal zero. If this is indeed the case, a freewheeling diode F1 or F2 is connected through and this oscillation behavior occurs, which is expressed in the potential changes.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A test assembly to emulate phase currents of an electric motor for testing a power electronics control unit adapted to control the electric motor and connectable to the test assembly, the test assembly comprising:
an inductor emulator that simulates the electric motor as an electrical load for the control unit using a power electronics circuit, and
a testing device to switch the inductor emulator to a different operating mode depending on an analysis of a variable dependent on an output voltage of the control unit.

2. The test assembly according to claim 1, wherein the inductor emulator acts as a power source.

3. The test assembly according to claim 1, wherein the inductor emulator is switched off in the different operating mode.

4. The test assembly according to claim 1, wherein the inductor emulator acts as a voltage source in the different operating mode.

5. The test assembly according to claim 1, wherein the testing device performs the analysis such that at least one change in the variable, dependent on the output voltage, is evaluated in a predefined first time interval and the switching of the inductor emulator to the different operating mode takes place as a function of this evaluation.

6. The test assembly according to claim 5, wherein the testing device has a threshold value comparator that compares the output voltage with at least one threshold value, and wherein the testing device performs the evaluation depending on this comparison.

7. The test assembly according to claim 5, wherein the threshold value comparator detects a rising and/or falling edge of the output voltage.

8. The test assembly according to claim 7, wherein the threshold value comparator compares the output voltage with at least two threshold values, wherein the threshold value comparator only detects a rising or falling edge based on the comparisons if the at least two threshold values are exceeded within a predefined second time interval.

9. The test assembly according to claim 7, wherein the testing device has a counter that counts rising edges or falling edges of the output voltage in a predefined third time interval that is as long as or shorter than the first predefined time interval, and wherein the testing device performs the evaluation depending on a counter reading of the counter.

10. The test assembly according to claim 1, wherein the testing device continues to analyze the variable dependent on the output voltage even after the inductor emulator has been switched off and to switch the inductor emulator on again depending on this further analysis.

11. The test assembly according to claim 1, wherein the inductor emulator has an inductor network to which the control unit is connected.

12. The test assembly according to claim 1, wherein the power electronics circuit has at least one bridge circuit with semiconductor switches or has three bridge circuits connected in parallel with semiconductor switches.

13. The test assembly according to claim 1, wherein the test assembly has a respective inductor emulator and a respective testing device for each respective phase of the electric motor.

14. A method for emulating phase currents of an electric motor by a test assembly for testing a power electronics control unit to control the electric motor and connectable to the test assembly, the method comprising:
providing an inductor emulator that simulates the electric motor as an electrical load for the control unit via a power electronics circuit, the inductor emulator acting as a power source; and
providing a testing device to switch the inductor emulator to a different operating mode depending on an analysis of a variable that depends on the output voltage of the control unit.

15. The method according to claim 14, wherein the analysis is carried out such that at least one change in the variable dependent on the output voltage is evaluated in a predefined first time interval and the inductor emulator is switched off as a function of this evaluation.

16. The method according to claim 15, wherein the variable dependent on the output voltage is compared with at least one threshold value and the evaluation is carried out depending on this comparison.

17. The test assembly according to claim 1, wherein the inductor emulator is switched to the different operating mode from a normal operating mode, wherein, in the normal operating mode, the inductor emulator provides phase currents, and wherein, in the different operating mode, the inductor emulator does not provide phase currents.
